(19) United States
(12) Patent Application Publication
(10) Pub. No.: US 2014/0291147 A1
(43) Pub. Date: Oct. 2, 2014

(54) TARGET MATERIALS FOR FABRICATING SOLAR CELLS

(71) Applicant: Delin Li, San Jose, CA (US)

(72) Inventor: Delin Li, San Jose, CA (US)

(73) Assignee: Soltrium Technology, LTD. Shenzhen, Shenzhen (CN)

(21) Appl. No.: 13/895,483

(22) Filed: May 16, 2013

(30) Foreign Application Priority Data
Mar. 28, 2013 (CN) 201310104882.1

(51) Int. Cl. C23C 14/34; H01L 31/18

(52) U.S. Cl. CPC C23C 14/3414; H01L 31/18
USPC 204/298.13; 438/73

(57) ABSTRACT

A sputtering target device is provided for manufacturing solar cells. The target device includes a metal selected from a group consisting of copper, indium, and molybdenum and further includes antimony or antimony-containing compound mixed in a matrix of the metal. The target device comprises antimony of 0.1 to 20 wt % and the metal of at least 80 wt %. The target device is installed in a deposition system for forming a back electrode doped with antimony or for forming at least one precursor layer doped with antimony among a stack of multiple precursor layers for forming a semiconductor photovoltaic absorber material.

### CROSS-REFERENCES TO RELATED APPLICATIONS

This application claims priority of Chinese Patent Application. No. 201310104882.1, filed on Mar. 28, 2013, by Delin Li, commonly assigned and incorporated by reference herein to its entirety for all purposes.

### BACKGROUND OF THE INVENTION

The present invention relates to target materials for fabricating semiconductors used for photovoltaic applications. Merely, by way of example, the present invention is applied to make sputtering targets used for the manufacture of thin-film photovoltaic material for solar cell, but it would be recognized that the invention has a much broader range of applications.

The solar cell utilizing photovoltaic effect converts sunlight directly into electricity. It is made of semiconductor materials specially functionalized to build an internal electric field of the depletion region, usually through a formation of p-n junction for driving electrons excited by photons. Basically, when sun light strikes the solar cell, a certain portion of the sun light is absorbed within the semiconductor material. The energy of the absorbed light is transferred to electrons in the atoms of the semiconductor material, which excites the electrons and knocks some loose from their association with the atoms, allowing them to flow freely. Through a build-in electric field across the p-n junction in each solar cell, a voltage is created to force those electrons freed by light absorption to flow in a certain direction. This flow of electrons is a current which could be collected by placing metal contacts on the top and bottom of the solar cell. This current, together with the solar cell's voltage associated with the built-in electric field, defines the power that the solar cell can produce.

One of the thin film solar cell technologies is to form the photovoltaic absorber from a copper indium gallium diselenide (sulfide) CIGS(S) compound semiconductor including at least copper (Cu), indium (In), gallium (Ga), selenium (Se), and/or sulfur(S) materials. It is referred to be CIGS technology. The state-of-art CIGS technology employing the CIGS(S) photovoltaic absorber has led to thin-film solar cell structures having conversion efficiencies approaching 20%. In an example, the CIGS thin-film solar cell is constructed with a junction of p-type Cu(InGa)Se₂ absorber and n-type CdS collector on a substrate configured with a metal back contact made by molybdenum material. After forming Cu(InGa)Se₂ thin-film absorber on a molybdenum material and a n-type CdS or ZnS material is formed over the CIGS absorber, forming a p-n junction between Cu(InGa)Se₂ and CdS or ZnS layers. A transparent conductive layer is then deposited on the CdS layer followed by a front contact layer to form the solar cell.

A wide variety of technologies have been used to make Cu(InGa)Se₂ photovoltaic absorber. One conventional method is to use evaporation process including depositions of all elemental species. Another conventional method is a two-stage process which is first to deposit thin film precursors including Cu, In, and Ga elemental species or their alloy followed by a selenization and/or sulfurization thermal annealing process. However, there are a lot of defects in the as-formed Cu(InGa)Se₂ absorber material using these conventional methods including sputtering deposition, which result in either low yield or low conversion efficiency of the solar cells. From the above, it is seen that improved techniques for manufacturing photovoltaic absorber materials and resulting solar cells are desired.

### BRIEF SUMMARY OF THE INVENTION

The present invention relates to target materials for sputtering thin films for fabricating photovoltaic absorber. Merely, by way of example, the present invention is applied to use these sputtering targets for making thin-film photovoltaic material for the manufacture of solar cells, but it would be recognized that the invention may have other configurations.

In a specific embodiment, the present invention provides a sputtering target for manufacturing solar cells. The sputtering target includes a metal element selected from a group consisting of copper, indium, gallium, and molybdenum metal. The sputtering target further includes antimony or an antimony-containing compound mixed in a matrix of the metal element. The sputtering target comprises antimony of 0.1 to 20 wt % and the metal of at least 80 wt %.

In another specific embodiment, the invention provides a sputtering target device comprising at least a metal element selected from copper, indium, gallium, and molybdenum. The sputtering target device further includes a sodium sulfide compound and antimony or an antimony-containing compound mixed in a matrix of the at least metal element, wherein said target device has antimony content of 0.1 to 15 wt %, sodium sulfide content of 0.1 to 5 wt %, and content of at least 80 wt % of the metal selected from copper, indium, gallium, and molybdenum.

In an alternative embodiment, the present invention provides a method of forming solar cells. The method includes providing a substrate and forming a back electrode layer overlying the substrate. The back electrode layer is a molybdenum-antimony alloy grown from a sputtering target comprising antimony of 0.1 to 15.0 wt % and molybdenum of at least 85 wt %. Alternatively, the back electrode layer is a molybdenum-antimony-sodium-sulfide formed from a sputtering target comprising antimony of 0.5 to 9.0 wt %, sodium sulfide of 0.1 to 5.0 wt %, and molybdenum of at least 86%. Additionally, the method includes forming a stack of multiple precursor layers overlying the back electrode layer. The stack of multiple precursor layers includes sequentially a first thickness of copper layer, a second thickness of indium layer, a third thickness of copper layer, a fourth thickness of gallium layer, and a fifth thickness of selenium layer. The method further includes subjecting the stack of multiple precursor layers to a thermal annealing process at a temperature between 450 and 600 Degrees Celsius for about 10 minutes to form an absorber material having antimony as a dopant. Furthermore, the method includes forming an n-type semiconductor comprising cadmium sulfide overlying the absorber material. Moreover, the method includes forming a zinc oxide layer overlying the n-type semiconductor followed by forming an aluminum doped zinc oxide layer over the zinc oxide layer and forming a front electrode overlying the aluminum doped zinc oxide layer.

In another alternative embodiment, the present invention provides a method of forming a solar cell. The method includes providing a substrate and forming a molybdenum layer as a back electrode overlying the substrate. Additionally, the method includes forming a stack of multiple precursor layers comprising copper, indium, gallium, and selenium sequentially overlying the back electrode. One of the multiple precursor layers is formed by sputtering from a target device comprising 0.1 to 20 wt % of antimony and at least 80 wt % of a metal element selected from a group of metal materials consisting of copper, indium, and gallium. The method further includes subjecting the substrate including the molybdenum layer and the stack of multiple precursor layers to a thermal annealing process at a temperature between 450 and 600 Degrees Celsius for about 10 minutes to form an absorber material having at least antimony as a dopant. Furthermore, the method includes forming an n-type semiconductor comprising cadmium sulfide overlying the absorber material. Moreover, the method includes forming a zinc oxide layer overlying the n-type semiconductor followed by forming an aluminum doped zinc oxide layer over the zinc oxide layer and forming a front electrode overlying the aluminum doped zinc oxide layer.

Many benefits can be achieved by applying the embodiments of the present invention. The present invention provides novel sputtering targets used for fabricating thin-film semiconductor materials for photovoltaic cell application. Embodiments of the invention includes making sputtering targets from ingredients selected from antimony (Sb) or antimony compound and at least one metal selected from a group consisting of copper (Cu), indium (In), gallium (Ga), selenium (Se), and molybdenum (Mo), and/or sodium sulfide (NaS). The present invention also provides a method of using the sputtering targets for forming a thin-film photovoltaic absorber material with substantial reduction of defects which results in larger grain size for chalcopyrite crystal structure of CIGS(S) photovoltaic absorber and improvement in cell conversion efficiency. Using these sputtering targets the manufacture process is simplified, leading to significantly lowered production costs. These and other benefits may be described throughout the present specification and more particularly below.

### BRIEF DESCRIPTION OF THE DRAWINGS

FIG. 1 is a simplified schematic diagram illustrating a system for fabricating solar cells by using a sputtering target of Sb-containing composite material according to an embodiment of the present invention;

FIG. 1A is a simplified diagram of a top view of a rectangle sputtering target of Sb-containing composite material according to an embodiment of the present invention;

FIG. 2 is a simplified cross sectional view of precursor layers formed on a substrate for fabricating CIGS solar cells according to an embodiment of the present invention;

FIG. 3 is a simplified cross sectional view of an absorber material formed from the precursor layers depicted in FIG. 2 for fabricating CIGS solar cells according to an embodiment of the present invention;

FIG. 4 is a simplified cross sectional view of a CIGS solar cell according to an embodiment of the present invention;

FIG. 5 is a simplified chart illustrating a method of fabricating CIGS solar cells according to an embodiment of the present invention;

FIG. 6 is a simplified chart illustrating a method of fabricating CIGS solar cells according to another embodiment of the present invention;

FIG. 7 is a simplified chart illustrating a method of fabricating CIGS solar cells according to yet another embodiment of the present invention;

FIG. 8 is a simplified chart illustrating a method of fabricating CIGS solar cells according to still another embodiment of the present invention;

FIG. 9 is a simplified chart illustrating a method of fabricating CIGS solar cells according to still yet another embodiment of the present invention;

FIG. 10 is a simplified chart illustrating a method of fabricating CIGS solar cells according to an alternative embodiment of the present invention; and

FIG. 11 is a simplified chart illustrating a method of fabricating CIGS solar cells according to another alternative embodiment of the present invention.

### DETAILED DESCRIPTION OF THE INVENTION

The present invention relates to target materials for sputtering thin films for fabricating photovoltaic absorber. Merely, by way of example, the present invention is applied to use these sputtering targets for making thin-film photovoltaic material for the manufacture of solar cells, but it would be recognized that the invention may have other configurations.

Conventional as-grown copper indium diselenide (CIS) based films comprise ternary chalcogenide compounds with intrinsically p-type semiconductor characteristics. Because of their direct and tunable energy bandgaps, high optical absorption coefficients in the visible to near infrared spectral range, these films have been major candidate as photovoltaic absorber material of thin film solar cells to deliver greater than 10% power conversion efficiency. Still other elements were added either as additional ingredient, e.g., gallium, or as dopants, e.g., aluminum, sodium, or sulfur, etc. for enhancing p-type conductivity or open-circuit voltage, and in turn, improving the photoelectron conversion efficiency of the copper indium gallium selenide (sulfide) CIGS based thin film solar cells up to as high as 20% in the lab. Besides tuning chemical composition of the absorber film, people have turned their attention to optimize other parameters like film thickness and grain size. Antimony doping into the film during the formation of CIGS based photovoltaic absorber is shown to result in substantial defect reduction and improvement in grain size. Throughout the specification, embodiments of present invention for making and using sputtering targets comprising antimony composite material to fabricate CIGS based photovoltaic absorber material of thin-film solar cells are provided.

A specific embodiment of the present invention includes making a sputtering target comprising copper antimony composite material. In an embodiment, a CuSb sputtering target comprises 0.8 wt % of antimony (Sb) and 99.2 wt % of copper (Cu). The CuSb sputtering target is made by mixing 0.8 wt % antimony powders and 99.2 wt % copper powders. The mixture of the Sb powder and Cu powder is thermal pressed together. Then a sintering process is performed in a furnace at a temperature near melting temperature of antimony to solidify the material into an object with specific form of a target support. Additional thermal treatments are carried out to form the sputtering target in various shapes. In an example, the CuSb sputtering target is made into a rectangular shape. Other shapes include round disk, round cylinder, hollowed cylinder, semi-hollowed cylinder, round ring, square, square ring, triangle, and more. The target device may include antimony-containing compound (metal alloy of antimony) instead of using pure antimony to mix with copper powder. The target device may contain a small trace of other impurities including selenium, aluminum, sulfur, or group VII or VIII elements.

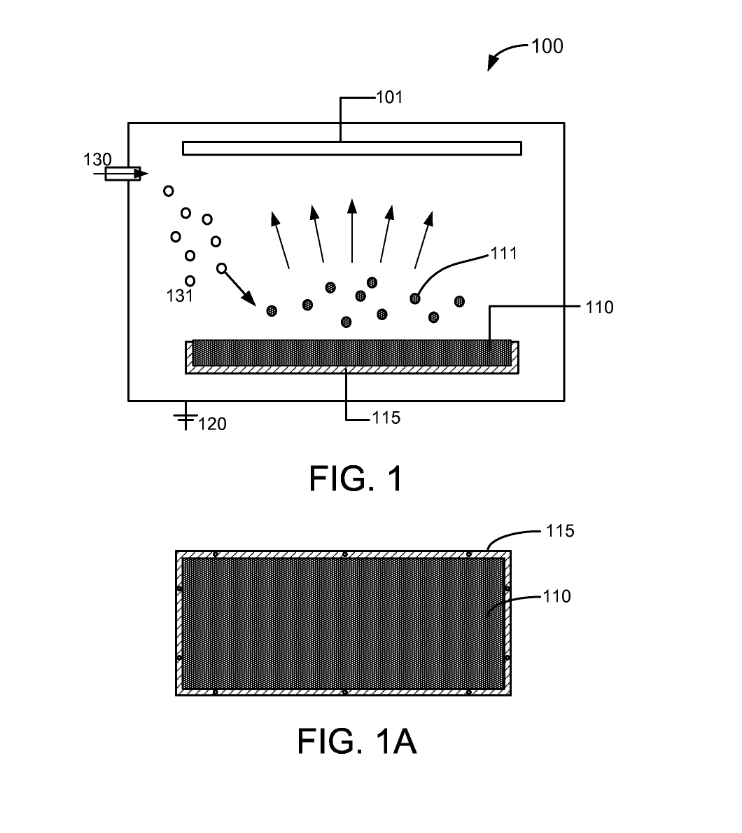

FIG. 1 is a simplified schematic diagram illustrating a system for fabricating solar cells by using a sputtering target of Sb-containing composite material according to an embodiment of the present invention. This diagram is merely an example, which should not unduly limit the scope of the claims herein. One skilled in the art would recognize other variations, modifications, and alternatives. As shown, a thin film deposition system 100 is provided to perform sputtering deposition of an antimony-doped thin film overlying a substrate 101 from a Sb-containing target device 110 disposed opposing to the substrate. The system 100 is a vacuum environment provided via a pump device 120 and the vacuum is filled with one or more inert gas via an inlet 130 to maintain a certain pressure as one of sputtering deposition condition. The substrate 101, which can be in any shape depending on embodiments, is disposed in the system and a DC or AC bias is applied across the substrate 101 and the sputtering target support 115 as another sputtering deposition condition. The electromagnetic field between the substrate and target ionizes the inert gas (usually Argon gas is used) and further accelerates the ions to hit surface of the target device 110. Atoms of target material are sputtered and ejected out and some are ionized too. These ionized species from target device 110 land on the surface of the substrate 101 to form a thin film over a deposition time. The substrate 101 can be held at near room temperature throughout the sputtering deposition process though sometime the temperature can be raised to desired elevated values (or desired temperature ranges). In an embodiment, the sputtering target 110 comprises at least one metal selected from a group consisting of copper, indium, gallium, and molybdenum. The sputtering target further includes antimony containing compound mixed into a matrix of the at least one metal selected from a group consisting of copper, indium, gallium, and molybdenum. The sputtering target comprises antimony of 0.1 to 20 wt % and the at least one metal of at least 80 wt %. For example, the metal in the sputtering target includes copper or indium.

In an embodiment, the target 110 is shaped to fit the substrate shape for providing substantially full coverage to the surface of the substrate 101. As an example, FIG. 1A shows a top view of a rectangle sputtering target of Sb-containing composite material according to an embodiment of the present invention. As shown, the target material 110 is fully enclosed in a planar rectangular shaped target support 115 excepting the exposed surface (for facing the substrate). The target support 115 can be made from stainless steel or other non-magnetic material and may include embedded tubes (not shown) to allow water cooling for target temperature control. In an alternative embodiment, the sputtering target 110 includes one or more metal element or alloy comprising copper, indium, gallium, and molybdenum material mixed with sodium sulfide compound and antimony-containing compound. The target device is formed as a bulk-shaped object held in the target support. The bulk-shaped object is sintered from powders of sodium sulfide, antimony, and the at least one metal element from copper, indium, gallium, and molybdenum with a composition range of 0.1 to 15 wt % of antimony, 0.1 to 5 wt % of sodium sulfide, and 80 to 99.8 wt % of the at least one metal element. The bulk-shaped object of the target device can be made with a rectangle shape as shown in FIG. 1A, other shapes like a round disk shape, a round cylinder shape, a hollowed cylinder shape, a semi-hollowed cylinder shape, a round ring shape, a square shape, or a triangle shape may be used and supported by a corresponding shaped target support. In another alternative embodiment, the sputtering target device 110 includes a matrix of molybdenum-containing alloy, sodium sulfide compound, and antimony-containing compound having a composition range of 0.1 to 15 wt % of antimony, 0.1 to 5 wt % of sodium sulfide, and 80 to 99.8 wt % of molybdenum and other elements.

Antimony-containing compound may be supplied for making the Sb-containing target, provided as pure antimony powders plus small amounts of selenium, aluminum, sulfur or group VII or VIII elements may exist as impurities that either do not materially affect or do not negatively affect the performance of CIGS layers deposited on a substrate by a sputtering process.

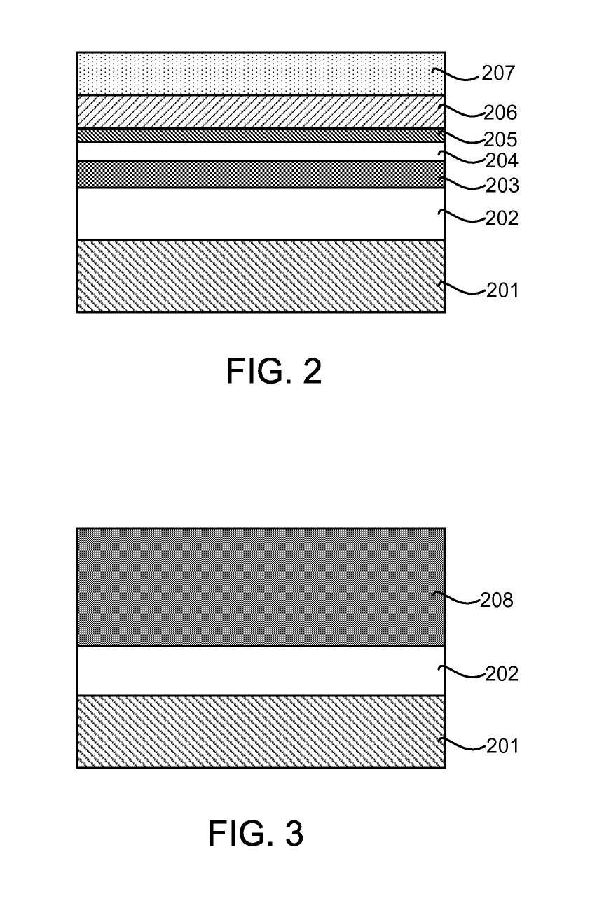

Another specific embodiment of the present invention includes using the sputtering target made from antimony-containing material for depositing a film doped with antimony during a formation process of precursor films for fabricating a CIGS based photovoltaic absorber material. FIG. 2 is a simplified cross sectional view of a stack of multiple precursor layers formed on a substrate for fabricating CIGS solar cells according to an embodiment of the present invention. This diagram is merely an example, which should not unduly limit the scope of the claims herein. One skilled in the art would recognize other variations, modifications, and alternatives. As shown, a substrate 201 is provided. A back electrode layer 202 is first formed overlying surface of the substrate 201. On the back electrode layer 202 a stack of multiple precursor layers is formed. A first thickness of a first precursor material 203 is formed overlying the back electrode layer 202. Furthermore, a second thickness of a second precursor material 204, a third thickness of a third precursor material 205, a fourth thickness of a fourth precursor material 206, and a fifth thickness of a fifth precursor material 207 are consecutively formed. In a specific embodiment, at least one layer of the stack of multiple precursor layers includes a film doped with antimony. The film is formed by sputtering deposition using one of the antimony-containing sputtering target devices made from the embodiments of the present invention. Some of the precursor materials are mainly metal material formed by electroplating. The multiple precursor materials are formed in consecutive order but the order can be adjusted and switched. One of the precursor materials may be formed before or after another of the precursor materials. Substantially, the formation of the multiple precursor materials is performed with the substrate 201 held at room temperature or at least less than 100° C. Of course, there are many alternatives, variations, and modifications.

Referring to FIG. 2, the substrate 201 can be provided with various types of materials, for example, glass, steel, or plastic. In an embodiment, the back electrode layer 202 is a film of molybdenum material in a thickness of about 1 μm deposited by sputtering, evaporation, electroplating, or printing. In an alternative embodiment, the back electrode layer 202 is a molybdenum alloy or composite material made from a sputtering deposition out of a target device according to an embodiment of the present invention. In an example, the target device is made by MoSb having about 1.0 to 10.0 wt % of antimony and 90 to 99 wt % of molybdenum. In another example, the target device is a MoSbNaS target made from 0.5 to 9.0 wt % of antimony, 0.1 to 5.0 wt % of sodium sulfide, and 86.0 to 99.6 wt % of molybdenum. A deposition system 100 may be used with the MoSb or MoSbNaS target device installed and Argon gas is supplied up to a predetermined pressure after the system is pumped to certain vacuum level. The deposition is carried with DC bias is applied between target and the substrate to form a MoSb or MoSbNaS alloy film 202 of about 1 μm in thickness overlying the substrate 201. In this embodiment, antimony is effective doped into the Mo-based back electrode layer. The antimony and sodium sulfide species therein may diffuse into upper precursor layers (formed later) to act as dopants to affect the structural-chemical-electrical properties of the as-formed CIGS photovoltaic absorber material. Of course, there are many alternatives, variations, and modifications.

As shown in FIG. 2, a stack of multiple precursor layers is formed consecutively over the back electrode 202. In an embodiment, the back electrode 202 is a molybdenum-based material comprising antimony and/or sodium sulfide. The stack of multiple precursor layers then is formed with a first thickness of copper layer 203, followed by a second thickness of indium layer 204, followed by a third thickness of copper layer 205, followed by a fourth thickness of gallium layer 206, and followed by a fifth thickness of selenium layer 207. In an alternative embodiment, the back electrode 202 is simply the molybdenum material. The stack of multiple precursor layers includes at least one layer formed by sputtering a target device comprising antimony (any/or sodium sulfide) and another metal selected from a group of metal materials consisting of copper, indium, and gallium. For example, a first precursor material 203 comprises a copper-antimony layer of about 0.25 μm in thickness deposited from a sputtering target comprising 0.5 to 9.0 wt % of antimony and 91 to 99.5 at % of copper. In a specific implementation of the invention, this target device is made according to one of embodiments of the present invention and the deposition system 100 (FIG. 1) is used. In another example, the third precursor material 205 is a copper-antimony layer bearing 0.5 to 9.0 wt % of antimony. Alternatively in a different implementation, a second precursor material 204 is just a layer of about 0.35 μm of indium-antimony alloy formed by sputtering a target device comprising antimony of 0.5 to 9.0 wt % and indium of 91 to 99.5 wt %. In yet another example, the first precursor material 203 includes a copper-antimony-sodium-sulfide film having a thickness of 0.25 mm deposited from a target device with 0.5 to 9.0 wt % of antimony, 0.1 to 5.0 wt % of sodium sulfide, and 86 to 99.6 wt % of copper. In still another example, the fourth precursor material 206 can be an indium-antimony film having a thickness of about 0.35 μm overlying a copper layer in the third precursor material 205. The indium-antimony film 206 is formed using the deposition system 100 equipped with a sputtering target comprising 0.5 to 9.0 wt % of antimony and 91 to 99.5 wt % of indium. Of course, there are many alternatives, variations, and modifications.

In another embodiment, the stack of multiple precursor layers is formed consecutively with certain predetermined orders. For example, the stack of multiple precursor layers includes a first precursor layer 203 which may be selected from a copper layer, or a copper-antimony alloy layer, or a copper-antimony-sodium-sulfide layer. The copper layer can be formed by sputtering deposition or electroplating process or a vacuum evaporation process. The copper-antimony layer and copper-antimony-sodium-sulfide layer can be formed respectively using target device mentioned above. The first precursor layer 203 is formed with a first thickness, e.g., about 0.25 μm. Additionally, a second precursor material 204 of the stack of multiple precursor layers may be selected from an indium layer, or a gallium layer, or an indium-antimony layer, with a second thickness, e.g., about 0.35 μm. Various deposition methods can be used while the indium-antimony layer is formed by sputtering a target device according to an embodiment of the present invention having antimony content of 0.5 to 9.0 wt % and indium content of 91 wt %. A third precursor layer 205 of the stack of multiple precursor layers includes material selected from copper and copper-antimony alloy, which can be formed using similar process for forming the first precursor layer 203. Furthermore, a fourth precursor layer 206 of the stack of multiple precursor layers includes material selected from gallium, or indium, or indium-antimony with a fourth thickness of about 0.35 μm. Finally, a fifth precursor layer 207 is formed with selenium material of a fifth thickness about 2 μm overlying the fourth precursor material 206 to complete the formation of the stack of multiple precursor layers. Of course, there are many alternatives, variations, and modifications. For example, the thickness of each layer in the stack of multiple precursor layers is a process variable that can be tuned to control, at least partially, a chemical stoichiometry of the stack of layers and a doping level of antimony or sodium sulfide in the stack that is designated to be transformed to a photovoltaic absorber material by a thermal process.

In yet another embodiment, the second precursor material 204 and the fourth precursor layer 206 may be swapped in order. In an example, either indium material or gallium material can be the choice for the second or the fourth precursor layer, with the third precursor layer 205 is copper-antimony film formed by sputtering a target device comprising 0.5 to 9.0 wt % of antimony and 91 to 99.5 at % of copper. In still yet another embodiment, a first precursor material 203 and the third precursor material 205 can be either a copper or a copper-antimony film. The copper-antimony film is formed by sputtering a target device comprising 0.5 to 9.0 wt % of antimony and 91 to 99.5 at % of copper. Of course, there are many alternatives, variations, and modifications.

After all the precursor materials are formed on the back electrode layer 202, the substrate 201 that carries all the layers formed thereafter, including the back electrode layer 202, a first thickness of a first precursor 203, a second thickness of a second precursor 204, a third thickness of a third precursor 205, a fourth thickness of a fourth precursor 206, and a fifth thickness of a fifth precursor 207 is subjected to a thermal anneal process. In a specific embodiment, the substrate 201 including all the precursor materials formed after is loaded into a furnace (not shown). The furnace can be pumped with a vacuum level then filled with an inert gas (e.g, nitrogen gas) for helping achieving temperature uniformity or mixed with certain reactive gas species that may be reacted with the precursors directly or be used for assisting the transformation of the precursors into a photovoltaic absorber material as desired. For example, nitrogen gas may be used. Reactive hydrogen selenide (H₂Se) gas species or hydrogen surfide (H₂S) gas species may be used during the annealing process.

In another specific embodiment, the thermal annealing process is performed with a predetermined temperature profile in which the subjected substrate 201 and corresponding precursor materials is annealed at a temperature between 450 and 600 Degrees Celsius for about 10 minutes before cooling down. The furnace temperature is ramped up from room temperature with a rate of about 10-20 Degrees per second. At this elevated temperature (range), all the precursor materials in layer 203, 204, 205, 206, 207 including some doped antimony species in the back electrode layer 202 are thermally activated, during which both physical diffusion and chemical reaction occur among the stack of multiple precursor layers and at least partially in the back electrode layer. In an embodiment, the composition in the film that contains antimony species from the targets made according to embodiments of the invention directly affect the physical diffusion process within the multilayer structure of the stack of precursor materials and partially in the back electrode layer including the antimony species itself. In another embodiment, the first thickness, the second thickness, the third thickness, the fourth thickness, and the fifth thickness selected respectively for forming each of the multiple precursor layers result in a desired stoichiometry for the as-annealed material, which forms a photovoltaic absorber material. In particular, the antimony content as well as the selected thicknesses of the stack of multiple precursor layers according to embodiments of the present invention described above determines the structural characteristics of the absorber material being a multi-grained CIGS ternary chalcogenide compound formed through the above annealing process with CIGS grain sizes close to absorber thickness with reduced number of defects. In turn, the absorber material is expected to provide enhanced photovoltaic conversion efficiency for the solar cells based these CIGS absorber materials with a proper stoichiometry. In a specific embodiment, the chemical stoichiometry of the CIGS chalcogenide absorber material includes a first ratio of copper/(indium+gallium) in a range of 0.75 to 0.95, a second ratio of gallium/(indium+gallium) in a range of 0.25 to 0.5, and a third ratio of selenium/(copper+indium+gallium) about 1.0. Of course, there are many alternatives, modifications, and variations.

FIG. 3 is a simplified cross sectional view of an absorber material formed from the stack of multiple precursor layers for fabricating CIGS solar cells according to an embodiment of the present invention. This diagram is merely an example, which should not unduly limit the scope of the claims herein. One skilled in the art would recognize other variations, modifications, and alternatives. As shown, a photovoltaic absorber 208 is formed overlying the back electrode layer 202. In fact, the photovoltaic absorber 208 is transformed by performing the thermal annealing process described above from the precursor materials 203, 204, 205, 206, 207 (FIG. 2) formed according to embodiments of the present invention. Depending on embodiments, the absorber 208 is a CIGS based ternary chalcogenide compound transformed by the multilayer precursor materials with specific first thickness, second thickness, third thickness, fourth thickness, and fifth thickness of layers as well as proper doping of antimony species through at least one of these precursor materials. In one embodiment, the antimony doping process is also carried out form the formation of a MoSb or MoSbNaS-based back electrode layer (202) overlying the substrate 201 (in that case, there may be no need to add any antimony-containing layers in the stack of multiple precursor layers). In another embodiment, the absorber material 208 formed overlying the back electrode layer 202 is characterized to be a p-type semiconductor. Of course, there are many alternatives, modifications, and variations.

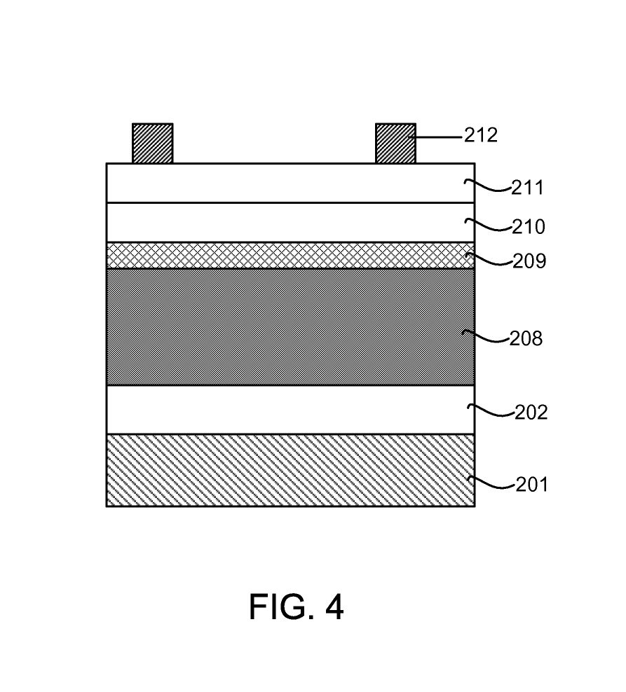

FIG. 4 is a simplified cross sectional view of a CIGS solar cell according to an embodiment of the present invention. This diagram is merely an example, which should not unduly limit the scope of the claims herein. One skilled in the art would recognize other variations, modifications, and alternatives. As shown, on top of a p-type absorber material 208 (FIG. 3) an n-type semiconductor material 209 is formed. The n-type semiconductor is a wide bandgap material allowing visible light to pass through and reach the p-type absorber material 208. In an example, the n-type semiconductor material 209 is cadmium sulfide (CdS) formed by a chemical bath deposition process overlying the CIGS absorber material 208 formed above according to embodiments of the present invention.

In a specific embodiment, followed the formation of the n-type semiconductor material 209 overlying the CIGS based p-type absorber material 208, a bi-layer zinc oxide material is formed overlying the n-type semiconductor material (FIG. 4). The bi-layer structure includes a zinc oxide layer 210 formed firstly overlying the n-type semiconductor CdS layer 209 and a zinc aluminum oxide layer 211 formed secondly overlying the previous zinc oxide layer 210. The bi-layer zinc oxide material is an optical transparent material and also a good electrical conductor (also called a window layer) which allows photons to pass through and be absorbed mainly by the absorber then converted to electrons. The conductive zinc oxide material also helps to collect these electrons driven by the p-n junction. Above the bi-layer zinc oxide material 210/211, a front electrode 212 is further deposited from a metal material source and a patterned grid structure is formed to complete the fabrication of a solar cell. The front electrode 212 is for transporting the electrical current generated by the solar cell.

One or more embodiments of the present invention provide methods for forming CIGS based thin film solar cells using at least one of antimony-containing sputtering target device to form at least one precursor material that contributes the formation of a CIGS based photovoltaic absorber material. Details of the methods can be found throughout the specification and more particularly below.

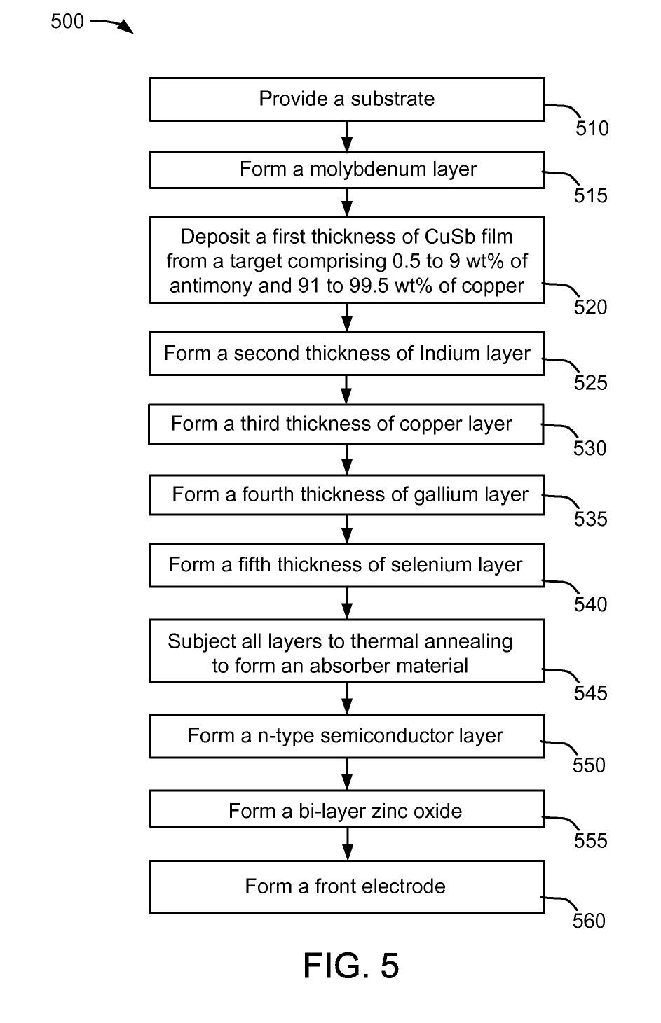

FIG. 5 is a simplified chart illustrating a method of fabricating CIGS solar cells according to an embodiment of the present invention. This diagram is merely an example, which should not unduly limit the scope of the claims herein. One skilled in the art would recognize other variations, modifications, and alternatives. As shown, the method 500 includes providing a substrate (step 510) for the manufacture of thin film solar cell. The method 500 further includes step 515 for forming a molybdenum layer overlying the substrate. This is illustrated in FIG. 2 as the molybdenum layer is the bottom electrode layer 202 formed overlying the substrate 201. In an example, the thickness of the molybdenum layer is about 1 μm. Additionally, the method 500 includes (step 520) forming a first thickness of copper antimony film overlying the molybdenum layer by sputtering deposition in a system filled with an inert gas from a CuSb target device comprising 0.5 to 9.0 wt % of antimony and 91 to 99.5 wt % of copper. The system used for performing sputtering deposition is substantially the deposition system 100 shown in FIG. 1, where the CuSb target device is pre-installed. In an example, the first thickness of the copper antimony film is about 0.2 μm. Furthermore, the method 500 includes (step 525) forming a second thickness of indium layer overlying the first thickness of copper antimony film followed by (step 530) forming a third thickness of copper layer overlying the indium layer. Moreover, a fourth thickness of gallium layer is formed (step 535) overlying the third thickness of copper layer followed by (step 540) forming a fifth thickness of selenium layer overlying the fourth thickness of gallium layer. In an example, the indium layer, the copper layer, the gallium layer, and the selenium layer are respectively deposited using electroplating technique, wherein the second thickness is about 0.35 μm, the third thickness is about 0.1 μm, the fourth thickness is about 0.12 μm, and the fifth thickness is about 2 μm.

FIG. 5 further shows the method 500 with a step 545 for subjecting the substrate including all layers formed thereon to a thermal annealing process at a temperate ramped between 450 and 600 Degrees Celsius for about 10 minutes to form an absorber material. The annealing temperature is ramped up from room temperature with a rate of about 10-20 Degrees per second. The annealing process transforms the stack of multiple precursor layers to an absorber material. In this case it is a copper-indium-gallium-diselenide (CIGS) compound, wherein the first thickness, the second thickness, the third thickness, the fourth thickness, and the fifth thickness of those corresponding layers formed over the molybdenum layer determine a proper stoichiometry of the CIGS compound. The antimony doped in the first thickness precursor layer contributes to make the absorber material a p-type semiconductor. Additionally, during the annealing process the antimony species doped through the first thickness of copper-antimony precursor layer further affects the structural properties of the absorber material with reduced defect number and enhanced grain size, all facilitating the photoelectrical current generation.

The method 500 further includes (step 550) forming an n-type semiconductor comprising cadmium sulfide overlying the absorber material and (step 555) forming a bi-layer zinc oxide overlying the n-type semiconductor. The bi-layer zinc oxide is an optical transparent and conductive material, comprising a zinc-oxide layer followed by an aluminum-doped zinc oxide layer. In particular, these steps form a window material which allows sun light to pass through and be absorbed by the CIGS absorber material and also is configured to collect the photo-electrons generated in the p-n junction. Moreover, the method 500 includes (step 560) forming a front electrode overlying the bi-layer zinc oxide to complete a fabrication of a thin-film solar cell. Of course, there are many process variations, alternatives, and modifications.

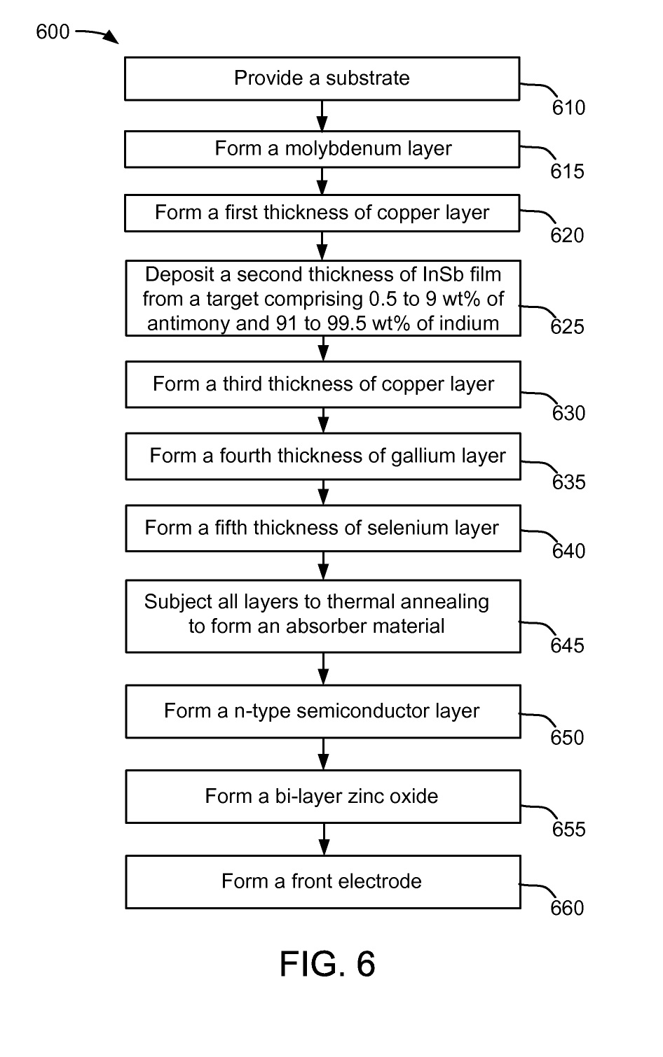

FIG. 6 is a simplified chart illustrating a method of fabricating CIGS solar cells according to another embodiment of the present invention. This diagram is merely an example, which should not unduly limit the scope of the claims herein. One skilled in the art would recognize other variations, modifications, and alternatives. As shown, the method 600 includes providing a substrate (step 610) for the manufacture of thin film solar cell. The method 600 further includes step 615 for forming a molybdenum layer overlying the substrate. This is illustrated in FIG. 2 as the molybdenum layer is the back electrode layer 202 formed overlying the substrate 201. In an example, the thickness of the molybdenum layer is about 1 μm. Additionally, the method 600 includes (step 620) forming a first thickness of copper layer by sputtering deposition or by evaporation. The first thickness is about 0.2 μm. Next a step 630 is to form a second thickness of indium antimony film overlying the first thickness of copper layer by sputtering deposition. The sputtering deposition is performed using a target device comprising 0.5 to 9 wt % of antimony and 91 to 99.5 wt % of indium. The system used for performing the sputtering deposition is substantially same as the deposition system 100 shown in FIG. 1, where the target device 110 is pre-installed. In an example, the second thickness of the indium antimony film is about 0.35 μm. Furthermore, the method 600 includes (step 630) forming a third thickness of copper layer overlying the second thickness of indium antimony film followed by (step 635) forming a fourth thickness of gallium layer overlying the third thickness of copper layer and followed by (step 640) forming a fifth thickness of selenium layer overlying the fourth thickness of gallium layer. In an example, the copper layer, gallium layer, and the selenium layer are respectively deposited using electroplating technique, wherein the third thickness is about 0.1 μm, the fourth thickness is about 0.12 μm, and the fifth thickness is about 2 μm.

FIG. 6 further shows the method 600 with a step 645 for subjecting the substrate including the molybdenum layer and all the stack of multiple precursor layers to a thermal annealing process at an annealing temperate between 450 and 600 Degrees Celsius for about 10 minutes to form an absorber material. The annealing temperature is ramped up from room temperature with a rate of about 10-20 Degrees per second. The as-formed absorber material is copper indium gallium diselenide (CIGS) compound, wherein the first thickness, the second thickness, the third thickness, the fourth thickness, and the fifth thickness of the stack of multiple precursor layers formed over the molybdenum layer determine a proper stoichiometry of the CIGS compound. The absorber material takes a p-type semiconductor characteristic from the doping of the antimony species through the second thickness of indium-antimony precursor layer. Antimony species further affect the structural properties of the absorber material in terms of defect reduction and grain size enlargement for facilitating photoelectrical current generation. The method 600 further includes (step 650) forming an n-type semiconductor comprising cadmium sulfide overlying the absorber material and (step 655) forming a zinc oxide material overlying the n-type semiconductor. The zinc oxide material is a conductive transparent bi-layer structure with a top layer aluminum-doped zinc oxide over a bottom layer of non-doped zinc oxide. In particular, these steps form a window material which allows sun light to pass through and be absorbed by the CIGS absorber and further facilitates the collection of the photo-electrons generated therein. Moreover, the method 600 includes (step 660) forming a front electrode overlying the bi-layer zinc oxide to complete a fabrication of a thin-film solar cell.

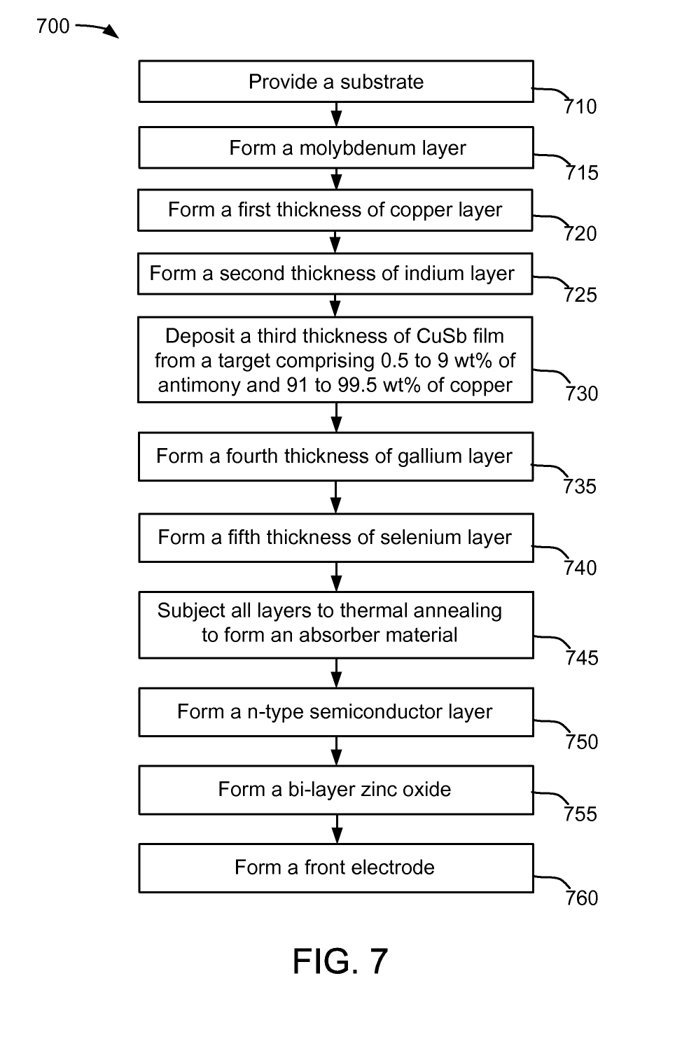

FIG. 7 is a simplified chart illustrating a method of fabricating CIGS solar cells according to yet another embodiment of the present invention. This diagram is merely an example, which should not unduly limit the scope of the claims herein. One skilled in the art would recognize other variations, modifications, and alternatives. As shown, the method 700 includes providing a substrate (step 710) for the manufacture of thin film solar cell. The method 700 further includes step 715 for forming a molybdenum layer as a back electrode overlying the substrate. This is illustrated in FIG. 2 as the back electrode 202 formed overlying the substrate 201. In an example, the thickness of the molybdenum layer is about 1 μm. Additionally, the method 700 includes (step 720) forming a first thickness of copper layer overlying the molybdenum layer. Then, the method 700 includes (step 725) forming a second thickness of indium layer overlying the first thickness of copper layer. Both the indium layer and the copper layer can be formed using an electroplating process or evaporation process. In an example, the first thickness is about 0.2 μm and the second thickness is about 0.35 μm. Furthermore, the method includes (step) 730) for forming a third thickness of copper-antimony film overlying the second thickness of indium layer by sputtering deposition from a target comprising 0.5 to 9 wt % of antimony and copper of at least 91 wt %. The system used for performing the sputtering deposition is substantially same as the deposition system 100 shown in FIG. 1, where the target 110 is pre-installed. In an example, the third thickness of the copper-antimony film is about 0.1 μm. The method 700 further includes (step 735) forming a fourth thickness of gallium layer overlying the third copper-antimony film followed by (step 740) forming a fifth thickness of selenium layer overlying the fourth thickness of gallium layer. In an example, the fourth thickness is about 0.12 μm and the fifth thickness is about 2 μm.

FIG. 7 further shows the method 700 with a step 745 for subjecting the substrate including the molybdenum layer and the stack of multiple precursor layers to a thermal annealing process performed at an annealing temperate between 450 and 600 Degrees Celsius for about 10 minutes to form an absorber material. The annealing temperature is ramped up from room temperature with a rate of about 10-20 Degrees per second. The as-formed absorber material is copper indium gallium diselenide (CIGS) compound, wherein the first thickness, the second thickness, the third thickness, the fourth thickness, and the fifth thickness of those layers formed over the molybdenum layer determine a proper stoichiometry of the CIGS compound. The CIGS absorber material takes a p-type semiconductor characteristic contributed by the antimony species doped through the third thickness of copper-antimony layer. The antimony species further may affect the structural properties with reduced defect number and enlarged grain size for facilitating photoelectrical current generation. The method 700 further includes (step 750) forming an n-type semiconductor comprising cadmium sulfide overlying the absorber material and (step 755) forming a zinc oxide bi-layer overlying the n-type semiconductor. The zinc-oxide bi-layer is a non-doped zinc oxide layer followed by an aluminum-doped zinc oxide layer. In particular, these steps form a window material which allows sun light to pass through and be absorbed by the CIGS absorber and further facilitates the collection of the photo-electrons generated therein. Moreover, the method 700 includes (step 760) forming a front electrode overlying the zinc oxide bi-layer to complete a fabrication of a thin-film solar cell.

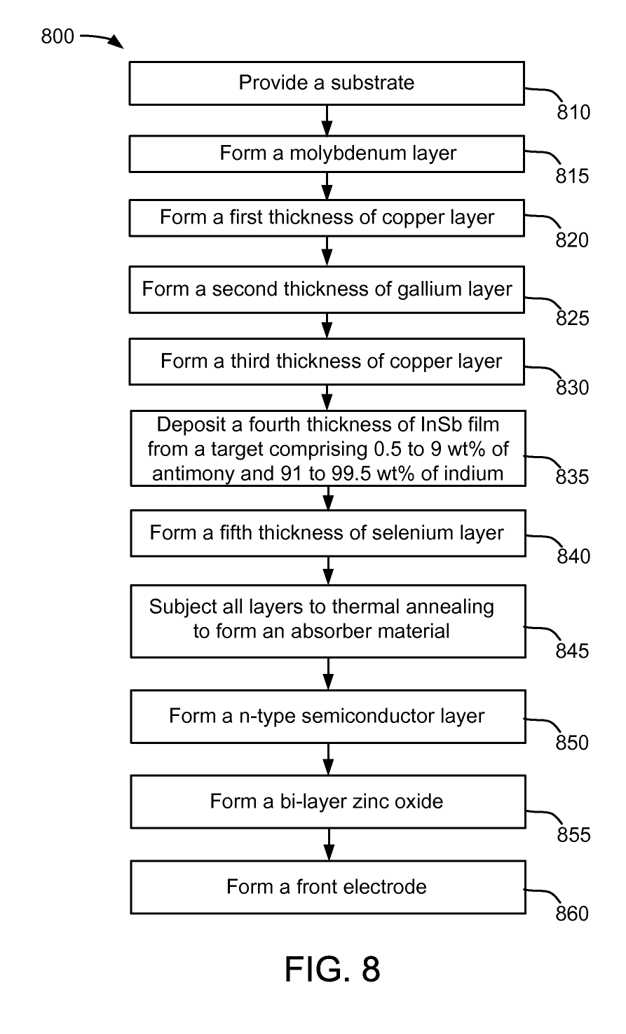

FIG. 8 is a simplified chart illustrating a method of fabricating CIGS solar cells according to still another embodiment of the present invention. This diagram is merely an example, which should not unduly limit the scope of the claims herein. One skilled in the art would recognize other variations, modifications, and alternatives. As shown, the method 800 includes providing a substrate (step 810) for the manufacture of thin film solar cell. The method 800 further includes step 815 for forming a molybdenum layer overlying the substrate. This is illustrated in FIG. 2 where the molybdenum layer forms a back electrode 202 overlying the substrate 201. In an example, the thickness of the molybdenum layer is about 1 μm. Additionally, the method 800 includes consecutive deposition process (steps 820-840) to form a stack of multiple precursor layers. These steps are substantially similar to the steps 520-540 except that the fourth precursor indium layer is replaced by a fourth thickness of indium antimony film formed by sputtering a target comprising 0.5 to 9 wt % of antimony and 91 to 99.5 wt % of indium. The substrate including all layers formed thereon is then subjected to a thermal annealing process (step 845) performed at an annealing temperate between 450 and 600 Degrees Celsius for about 10 minutes to form an absorber material. The annealing temperature is ramped up from room temperature with a rate of about 10-20 Degrees per second. The thicknesses of the corresponding layers of the multiple precursor layers determine a chemical stoichiometry of the as-formed absorber material which is a multi-grained copper-indium-gallium-diselenide CIGS compound. The antimony species provided through the fourth thickness of InSb film contribute to a formation of p-type characteristic of the absorber material and may also affect the structural properties of the CIGS compound by reducing its defect in grains and enlarging the grain size for facilitating photoelectrical current generation. The method 800 further includes (step 850) forming an n-type semiconductor comprising cadmium sulfide overlying the absorber material and (step 855) forming a zinc oxide bi-layer overlying the n-type semiconductor. The zinc-oxide bi-layer is a non-doped zinc oxide layer followed by an aluminum-doped zinc oxide layer. In particular, these steps form a window material which allows sun light to pass through and be absorbed by the CIGS absorber and further facilitates the collection of the photo-electrons generated therein. Moreover, the method 800 includes (step 860) forming a front electrode overlying the zinc oxide bi-layer to complete a fabrication of a thin-film solar cell.

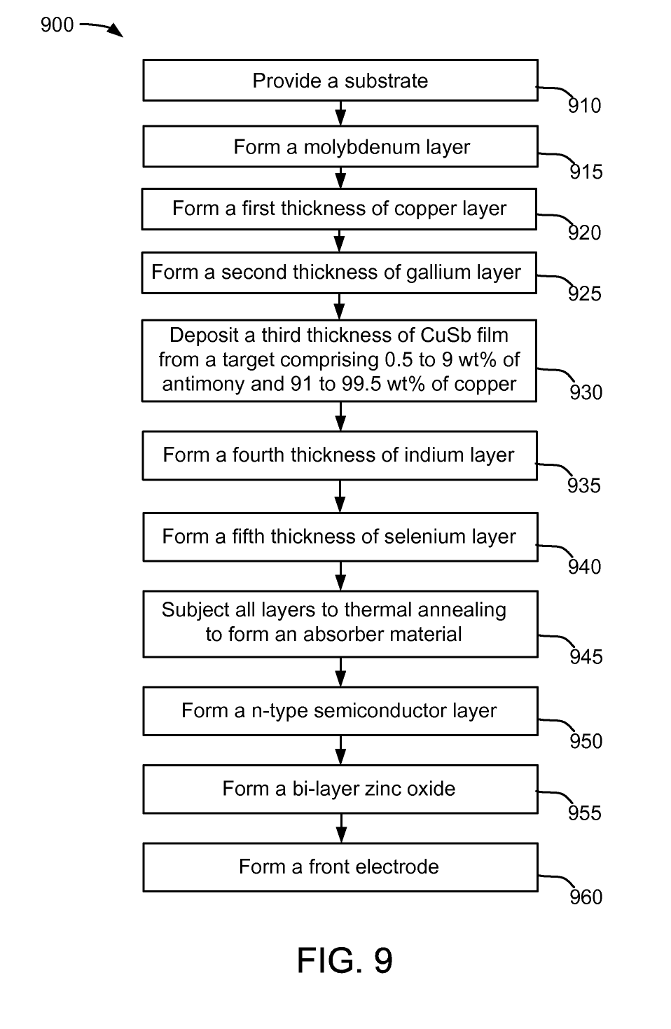

FIG. 9 is a simplified chart illustrating a method of fabricating CIGS solar cells according to still yet another embodiment of the present invention. This diagram is merely an example, which should not unduly limit the scope of the claims herein. One skilled in the art would recognize other variations, modifications, and alternatives. As shown, the method 900 includes providing a substrate (step 910) for the manufacture of thin film solar cell. The method 900 further includes step 915 for forming a molybdenum layer overlying the substrate. This is illustrated in FIG. 2 where the molybdenum layer forms a back electrode 202 overlying the substrate 201. In an example, the thickness of the molybdenum layer is about 1 μm. Additionally, the method 900 includes consecutive deposition process (steps 920-940) to form a stack of multiple precursor layers. These steps are substantially similar to the steps 720-740 except that the second precursor layer and the fourth precursor layer are swapped. The third layer of this stack of multiple precursor layers is a copper-antimony film of about 0.1 μm deposited by sputtering a target device comprising antimony of 0.5 to 9.0 wt % and copper of at least 91 wt %. Subsequently, the substrate including all layers formed thereon is then subjected to a thermal annealing process (step 945) performed at an annealing temperate between 450 and 600 Degrees Celsius for about 10 minutes to form an absorber material. The annealing temperature is ramped up from room temperature with a rate of about 10-20 Degrees per second. The thicknesses of the corresponding layers of the multiple precursor layers determine a chemical stoichiometry of the as-formed absorber material which is a multi-grained copper-indium-gallium-diselenide CIGS compound. In an embodiment, a preferred stoichiometry of the CIGS photovoltaic absorber material includes a first ratio of copper/(indium+gallium) in a range of 0.75 to 0.95, a second ratio of gallium/(indium+gallium) in a range of 0.25 to 0.5, and a third ratio of selenium/(copper+indium+gallium) about 1.0. The antimony species provided through the third thickness of CuSb film contribute to a formation of p-type characteristic of the absorber material and may also affect the structural properties of the CIGS compound by reducing its defect in grains and enlarging the grain size for facilitating photoelectrical current generation. The method 900 further includes (step 950) forming an n-type semiconductor comprising cadmium sulfide overlying the absorber material and (step 955) forming a zinc oxide bi-layer overlying the n-type semiconductor. The zinc-oxide bi-layer is a non-doped zinc oxide layer followed by an aluminum-doped zinc oxide layer. In particular, these steps form a window material which allows sun light to pass through and be absorbed by the CIGS absorber and further facilitates the collection of the photo-electrons generated therein. Moreover, the method 900 includes (step 960) forming a front electrode overlying the zinc oxide bi-layer to complete a fabrication of a thin-film solar cell.

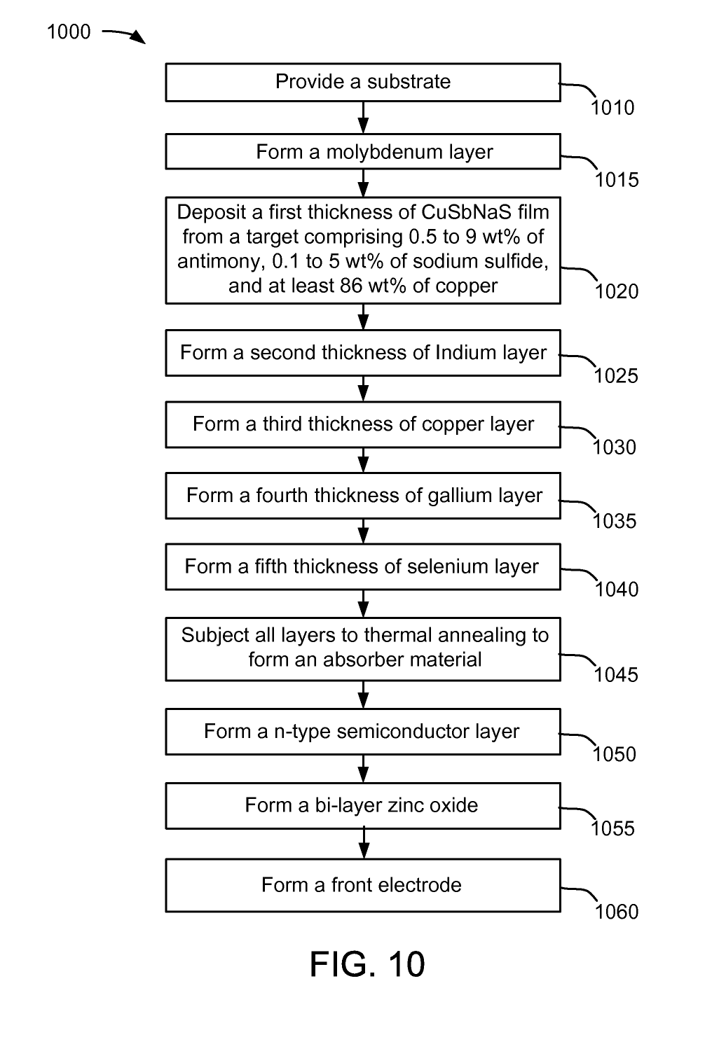

FIG. 10 is a simplified chart illustrating a method of fabricating CIGS solar cells according to a different embodiment of the present invention. This diagram is merely an example, which should not unduly limit the scope of the claims herein. One skilled in the art would recognize other variations, modifications, and alternatives. As shown, the method 1000 includes providing a substrate (step 1010) for the manufacture of thin film solar cell. The method 1000 further includes step 1015 for forming a molybdenum layer overlying the substrate. This is illustrated in FIG. 2 where the molybdenum layer forms a back electrode 202 overlying the substrate 201. In an example, the thickness of the molybdenum layer is about 1 μm. Additionally, the method 1000 includes (step 1020) forming a first thickness of copper-antimony-sodium-sulfide (CuSbNaS) film overlying the molybdenum layer by sputtering deposition from a target comprising 0.5 to 9 wt % of antimony, 0.1 to 5 wt % of sodium sulfide, and at least 86 wt % of copper. The system used for performing the sputtering deposition is substantially same as the deposition system 100 shown in FIG. 1, where the target 110 is pre-installed. In an example, the first thickness of the copper-antimony-sodium-sulfide film is about 0.2 μm. Furthermore, the method 1000 includes other deposition processes (steps 1025-1040) for forming other layers of the stack of multiple precursor layers. These steps are substantially similar to the steps 525-540 to include an second thickness of indium layer, a third thickness of copper layer, a fourth thickness of gallium layer, and a fifth thickness of selenium layer respectively deposited using electroplating technique or evaporation technique. Correspondingly, in an example, the second thickness is about 0.35 μm, the third thickness is about 0.1 μm, the fourth thickness is about 0.12 μm, and the fifth thickness is about 2 μm.

FIG. 10 further shows a step 1045 in which the substrate including all layers formed thereon is subjected to a thermal annealing process performed at an annealing temperate between 450 and 600 Degrees Celsius for about 10 minutes to form an absorber material. The annealing temperature is ramped up from room temperature with a rate of about 10-20 Degrees per second. The thicknesses of the corresponding layers of the multiple precursor layers determine a chemical stoichiometry of the as-formed absorber material which is a multi-grained copper-indium-gallium-diselenide CIGS compound. In an embodiment, a preferred stoichiometry of the CIGS photovoltaic absorber material includes a first ratio of copper/(indium+gallium) in a range of 0.75 to 0.95, a second ratio of gallium/(indium+gallium) in a range of 0.25 to 0.5, and a third ratio of selenium/(copper+indium+gallium) about 1.0. The antimony species provided through the first thickness of CuSbNaS film contribute to a formation of p-type characteristic of the absorber material and may also affect the structural properties of the CIGS compound by reducing its defect in grains and enlarging the grain size for facilitating photoelectrical current generation. The method 1000 further includes (step 1050) forming an n-type semiconductor comprising cadmium sulfide overlying the absorber material and (step 1055) forming a zinc oxide bi-layer overlying the n-type semiconductor. The zinc-oxide bi-layer is a non-doped zinc oxide layer followed by an aluminum-doped zinc oxide layer. In particular, these steps form a window material which allows sun light to pass through and be absorbed by the CIGS absorber material and further facilitates the collection of the photo-electrons generated therein. Moreover, the method 1000 includes (step 1060) forming a front electrode overlying the zinc oxide bi-layer to complete a fabrication of a thin-film solar cell.

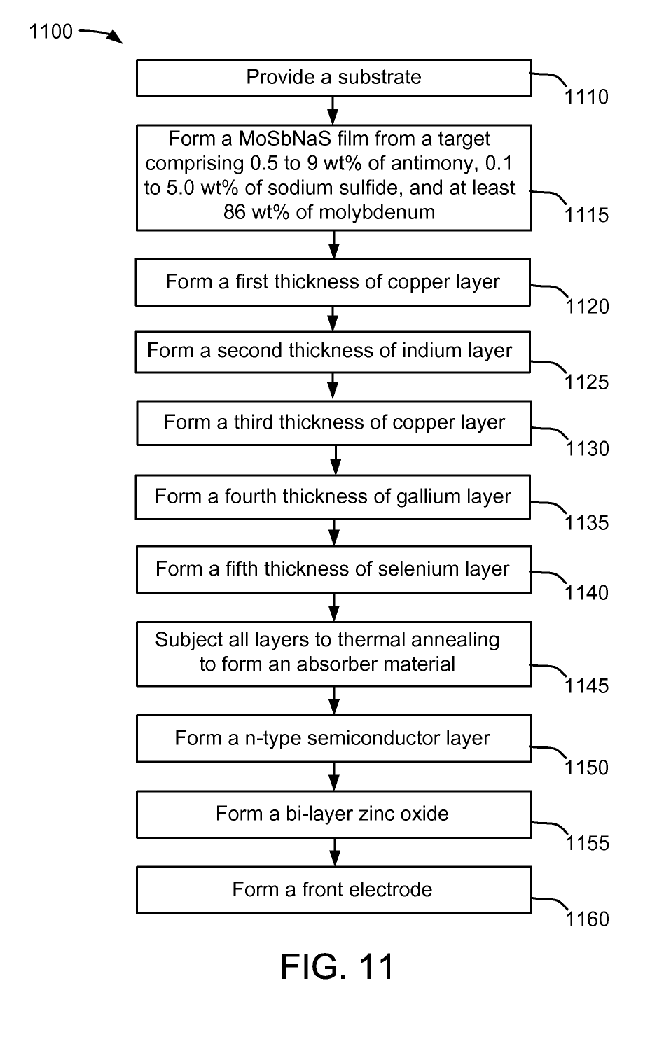

FIG. 11 is a simplified chart illustrating a method of fabricating CIGS solar cells according to another alternative embodiment of the present invention. This diagram is merely an example, which should not unduly limit the scope of the claims herein. One skilled in the art would recognize other variations, modifications, and alternatives. As shown, the method 1100 includes providing a substrate (step 1110) for the manufacture of thin film solar cell. This is illustrated in FIG. 2 as the substrate 201 is provided. The method 1100 further includes step 1115 for forming a molybdenum antimony sodium sulfide (MoSbNaS) film overlying the substrate 201 by sputtering deposition from a target comprising 0.5 to 9.0 wt % of antimony, 0.1 to 5.0 wt % of sodium sulfide, and at least 86 wt % of molybdenum. The system used for performing the sputtering deposition is substantially same as the deposition system 100 shown in FIG. 1, where the target 110 is pre-installed. In an example, the thickness of the MoSbNaS film is about 1 μm. Alternatively, this film can be a MoSb film formed by sputtering a target with antimony content of 0.5 to 9.0 wt % and molybdenum content of at least 91%. This is also illustrated in FIG. 2 as the MoSbNaS film or MoSb serves as a back electrode layer 202 doped with antimony. Additionally, the method 1100 includes a series of deposition processes (steps 1020-1040) to form a stack of multiple precursor layers sequentially including a first thickness of copper layer, a second thickness of indium layer, a third thickness of copper layer, a fourth thickness of gallium layer, and a fifth thickness of selenium layer. In an example, the first thickness of the copper layer is about 0.2 μm formed by electroplating or evaporating technique. The second thickness is about 0.35 μm, the third thickness is about 0.1 μm, the fourth thickness is about 0.12 μm, and the fifth thickness is about 2 μm.

FIG. 11 further shows the method 1100 with a step 1140 for subjecting the substrate including the MoSbNaS or MoSb film as the back electrode plus the stack of precursor layers to a thermal annealing process at an annealing temperate between 450 and 600 Degrees Celsius for about 10 minutes to form an absorber material. The annealing temperature is ramped up from room temperature with a rate of about 10-20 Degrees per second. The thicknesses of the corresponding layers of the multiple precursor layers determine a chemical stoichiometry of the as-formed absorber material which is a multi-grained copper-indium-gallium-diselenide CIGS compound. In an embodiment, a preferred stoichiometry of the CIGS photovoltaic absorber material includes a first ratio of copper/(indium+gallium) in a range of 0.75 to 0.95, a second ratio of gallium/(indium+gallium) in a range of 0.25 to 0.5, and a third ratio of selenium/(copper+indium+gallium) about 1.0. The antimony species provided through the MoSbNaS back electrode layer diffuse into the stack of multiple precursor layers and contribute to a formation of p-type characteristic of the absorber material and may also affect the structural properties of the CIGS compound by reducing its defect in grains and enlarging the grain size for facilitating photoelectrical current generation. The method 1100 further includes (step 1150) forming an n-type semiconductor comprising cadmium sulfide overlying the absorber material and (step 1155) forming a zinc oxide bi-layer overlying the n-type semiconductor. The zinc-oxide bi-layer is a non-doped zinc oxide layer followed by an aluminum-doped zinc oxide layer. In particular, these steps form a window material which allows sun light to pass through and be absorbed by the CIGS absorber material and further facilitates the collection of the photo-electrons generated therein. Moreover, the method 1100 includes (step 1160) forming a front electrode overlying the zinc oxide bi-layer to complete a fabrication of a thin-film solar cell.

It is also understood that the examples, figures, and embodiments described herein are for illustrative purposes only and that various modifications or changes in light thereof will be suggested to persons skilled in the art and are to be included within the spirit and purview of this application and scope of the appended claims.

What is claimed is:

1. A sputtering target device for manufacturing solar cells comprising:
metal from a group consisting of copper, indium, and molybdenum; and
antimony or an antimony-containing compound mixed in a matrix of the metal, wherein said target device comprises antimony of 0.1 and 20 wt % and the metal of at least 80 wt %.

2. The sputtering target device of claim 1 wherein said target device comprises antimony of 0.5 to 9.0 wt % and copper of 91.0 to 99.5 wt %.

3. The sputtering target device of claim 1 wherein said target device comprises antimony of 1.0 to 10 wt % and indium of 90.0 to 99.0 wt %.

4. The sputtering target device of claim 1 wherein said target device comprises antimony of 1.0 to 10 wt % and molybdenum of 90.0 to 99.0 wt %.

5. The sputtering target device of claim 1 wherein said target device comprises a bulk shaped material formed by sintering a powder mixture of the metal and the antimony-containing compound in a target support, the bulk shaped material being characterized by a shape selected from rectangle, disk, cylinder, hollowed cylinder, semi-hollowed cylinder, ring, square, and triangle.

6. A sputtering target device comprising:
at least a metal selected from copper, indium, and molybdenum;
a sodium sulfide compound; and
an antimony or an antimony-containing compound mixed in a matrix of the at least the metal with the sodium sulfide compound, wherein said target device comprises antimony of 0.1 to 15 wt %, sodium sulfide of 0.1 to 5 wt %, and the at least the metal of at least 80 wt %.

7. The target device of claim 6 wherein said target device comprises antimony of 0.5 to 9.0 wt %, sodium sulfide of 0.1 to 5.0 wt %, and copper of at least 86 wt %.

8. The target device of claim 6 wherein said target device comprises antimony of 0.5 to 9.0 wt %, sodium sulfide of 0.1 to 5.0 wt %, and indium of at least 86 wt %.

9. The target device of claim 6 wherein said target device comprises antimony of 0.5 to 9.0 wt %, sodium sulfide of 0.1 to 5.0 wt %, and molybdenum of at least 86 wt %.

10. A method of making solar cells comprising:
providing a substrate;
forming a back electrode layer overlying the substrate, wherein the back electrode layer is a molybdenum-antimony alloy grown from a sputtering target comprising antimony of 0.1 to 15.0 wt % and molybdenum of at least 85 wt %;
forming a stack of multiple precursor layers overlying the back electrode layer, wherein the stack of multiple precursor layers comprises a first thickness of copper layer, a second thickness of indium layer, a third thickness of copper layer, a fourth thickness of gallium layer, and a fifth thickness of selenium layer;
subjecting the stack of multiple precursor layers to a thermal annealing process at a temperature between 450 and 600 Degrees Celsius for about 10 minutes to form an absorber material having antimony as a dopant;
forming an n-type semiconductor comprising cadmium sulfide overlying the absorber material;
forming a zinc oxide layer overlying the n-type semiconductor followed by forming an aluminum doped zinc oxide layer over the zinc oxide layer; and
forming a front electrode overlying the aluminum doped zinc oxide layer.

11. The method of claim 10 wherein the absorber material comprises a copper-indium-gallium-selenide compound having a chemical stoichiometry of determined by the first thickness, the second thickness, the third thickness, the fourth thickness, and the fifth thickness of corresponding precursor layers, the copper-indium-gallium-selenide compound comprising antimony doped via the back electrode layer.

12. The method of claim 10 wherein the chemical stoichiometry comprises a first ratio of copper/(indium+gallium) in a range of 0.75 to 0.95, a second ratio of gallium/(indium+gallium) in a range of 0.25 to 0.5, and a third ratio of selenium/(copper+indium+gallium) about 1.0.

13. A method of making solar cells comprising:
providing a substrate;
forming a molybdenum layer as a back electrode overlying the substrate;
forming a stack of multiple precursor layers comprising copper, indium, gallium, and selenium sequentially overlying the back electrode, wherein one of the multiple precursor layers is formed by sputtering from a target device comprising 0.1 to 20 wt % of antimony and at least 80 wt % of a metal element selected from a group of metal materials consisting of copper, indium, and gallium;
subjecting the substrate including the molybdenum layer and the stack of multiple precursor layers to a thermal annealing process at a temperature between 450 and 600 Degrees Celsius for about 10 minutes to form an absorber material having at least antimony as a dopant;
forming an n-type semiconductor comprising cadmium sulfide overlying the absorber material;
forming a zinc oxide layer overlying the n-type semiconductor followed by forming an aluminum doped zinc oxide layer over the zinc oxide layer; and
forming a front electrode overlying the aluminum doped zinc oxide layer.

14. The method of claim 13 wherein the stack of multiple precursor layers comprises:
a first thickness of copper-antimony layer formed from sputtering a target device comprising antimony of 0.5 to 9.0 wt % and copper of at least 91 wt %;
a second thickness of indium layer;
a third thickness of copper layer;
a fourth thickness of gallium layer; and
a fifth thickness of selenium layer.

15. The method of claim 13 wherein the stack of multiple precursor layers comprises:
a first thickness of copper layer;
a second thickness of indium-antimony layer formed from sputtering a target device comprising antimony of 0.5 to 9.0 wt % and indium of at least 91 wt %;
a third thickness of copper layer;
a fourth thickness of gallium layer; and
a fifth thickness of selenium layer.

16. The method of claim 13 wherein the stack of multiple precursor layers comprises:
a first thickness of copper layer;
a second thickness of indium layer;
a third thickness of copper-antimony layer formed from sputtering a target device comprising antimony of 0.5 to 9.0 wt % and copper of at least 91 wt %;
a fourth thickness of gallium layer; and
a fifth thickness of selenium layer.

17. The method of claim 13 wherein the stack of multiple precursor layers comprises:
a first thickness of copper layer;
a second thickness of gallium layer;
a third thickness of copper layer;
a fourth thickness of indium-antimony layer formed from sputtering a target device comprising antimony of 0.5 to 9.0 wt % and indium of at least 91 wt %; and
a fifth thickness of selenium layer.

18. The method of claim 13 wherein the stack of multiple precursor layers comprises:
a first thickness of copper layer;
a second thickness of gallium layer;
a third thickness of copper-antimony layer formed from sputtering a target device comprising antimony of 0.5 to 9.0 wt % and copper of at least 91 wt %;
a fourth thickness of indium layer; and
a fifth thickness of selenium layer.

19. The method of claim 13 wherein the absorber material comprises a copper-indium-gallium-selenide compound having a chemical stoichiometry of determined by corresponding thicknesses of the multiple precursor layers including at least one layer doped by antimony.

20. The method of claim 19 wherein the chemical stoichiometry comprises a first ratio of copper/(indium+gallium) in a range of 0.75 to 0.95, a second ratio of gallium/(indium+gallium) in a range of 0.25 to 0.5, and a third ratio of selenium/(copper+indium+gallium) about 1.0.
